(19) United States
(12) Patent Application Publication
(10) Pub. No.: US 2016/0202331 A1
(43) Pub. Date: Jul. 14, 2016

(54) IDENTIFICATION SYSTEM AND METHOD FOR SHIELDED MAGNETIC UNIT

(71) Applicant: National Taiwan University, Taipei (TW)

(72) Inventors: Bing-Yu Chen, Taipei (TW); Rong-Hao Liang, Taipei (TW); Liwei Chan, Taipei (TW); Han-Chih Kuo, Taipei (TW); De-Nian Yang, Taipei (TW)

(21) Appl. No.: 14/701,950

(22) Filed: May 1, 2015

(30) Foreign Application Priority Data
Jan. 8, 2015 (TW) 104100498

(51) Int. Cl. G01R 33/10

(52) U.S. Cl. CPC G01R 33/10

(57) ABSTRACT

The present invention provides an identification system and an identification method for a shielded magnetic unit. A shielding element is disposed at periphery of a magnet in a shield of a magnetic unit, such that the magnetic line of the magnet is directed back inside the shield. Moreover, after the identification system for a magnetic unit obtains a data curve to be identified of the shield, the data curve to be identified of the shield can be compared with a plurality of sets of characteristic data curves, so as to define an identification code of the magnetic unit. Accordingly, the present invention can solve the problem of interference and difficult identification while simultaneously detecting a plurality of magnetic units.

### BACKGROUND OF THE INVENTION

1. Field of the Invention

The present invention relates to identification technique for magnetic units, and, more particularly, to a system and a method using magnetic force sensing technique for recognizing or analyzing the position or direction of shielded magnetic units.

2. Description of Related Art

In recent years, a new human-computer interaction is constantly being raised, so that users can interact with electronic devices in a more intuitive operation manner. In the existing human-computer interaction techniques, in addition to allowing users to receive full visual feedback effects from the screen display, physical object can be used to operate digital information in the screen, such that users can get rich tactile feedback effects.

In the conventional human-computer interaction, technical means of analyzing the magnetic field information of a magnet to determine the position of the magnet has been known. However, when a plurality of magnets are concurrently placed in the same plane for performing analysis, such technique may cause a problem of interference and difficult identification since the magnetic attraction and repulsion between respective magnets lead the merge or cancellation of magnetic fields. According, user operation is obstructed.

Therefore, it has been an issued desired to be solved that how to provide an identification system and method for magnet to effectively detect a plurality of magnets, while further providing identification codes for respective magnets, so as to solve above deficiencies of interference and difficult identification.

### SUMMARY OF THE INVENTION

In order to solve the aforementioned deficiencies of prior art, an objective of the present invention is to provide an identification system for a shielded magnetic unit, comprising: at least one magnetic unit having at least one shield disposed therein, wherein the shield includes at least one magnet and a shielding element disposed at periphery of the magnet; a magnetic field sensor constructed by a plurality of magnetic sensing units arranged in an array form, wherein the magnetic field sensor senses a magnetic field of the magnet of the shield to generate a magnetic sensing signal; and a computing unit, comprising: a characteristic database storing a plurality of sets of characteristic data curves, wherein the plurality of sets of characteristic data curves are established according to shields corresponding to different polarities and intensities, respectively and each of the plurality of sets of characteristic data curves has an identification code different from one another; a curve establishing module for converting the magnetic sensing signal into a data curve to be identified; and an identifying module for selecting one most similar to the data curve to be identified from the plurality of sets of characteristic data curves, such that the identification code of the one most similar to the data curve to be identified is defined as an identification code of the magnetic unit.

Another objective of the present invention is to provide a method of identifying a shielded magnetic unit, comprising steps of: a) obtaining a bitmap image of magnetic field of a shield in a magnetic unit; b) applying a plurality of intensity threshold values of the magnetic field for magnetic fields of an N pole and an S pole in the bitmap image of the magnetic field to obtain at least one contour of different intensities of the magnetic fields of the N pole and S pole; c) calculating area values each representing an area enclosed by each of the plurality of contours, such that a characteristic data curve of the shield is drawn by using the area values and corresponding intensity threshold values of the magnetic field as two-dimensional coordinates; and d) selecting one most similar to the characteristic data curve of the shield from at least one set of characteristic data curves with defined identification codes, such that the identification code of the one most similar to the characteristic data curve of the shield is defined as an identification code of the magnetic unit.

A further objective of the present invention is to provide a method of identifying a shielded magnetic unit, comprising steps of: a) obtaining bitmap images of a magnetic field of each of a plurality of shields in a magnetic unit; b) applying at least one intensity threshold values of the magnetic field for magnetic fields of an N pole and an S pole in each of the bitmap images of the magnetic field to obtain at least one contour of different intensities of the magnetic fields of the N pole and the S pole in each of the bitmap images of the magnetic field; c) calculating an area value representing an area enclosed by the contour in each of the bitmap images of the magnetic field, such that characteristic data curves of the shields are drawn by using the area values and corresponding intensity threshold values of the magnetic field as two-dimensional coordinates, respectively; d) selecting ones most similar to the characteristic data curves of the shields from a plurality of sets of characteristic data curves with defined identification codes, respectively, such that the identification codes of the ones most similar to the characteristic data curves of the shields are defined as identification codes of the shields, respectively; and e) defining an identification code of the magnetic unit by an equation.

As compared with the prior art, the present invention provides an identification system and method for shielded magnetic units. Since a shielding element is disposed at periphery of a magnet in a shield of the magnetic unit, the magnetic line of the magnet is directed back inside the shield to reduce the interference occurred while simultaneously detecting a plurality of magnetic units. Moreover, a plurality of sets of characteristic data curves are established in advance, such that a data curve to be identified of the shield can be compared with the plurality of sets of data curves to select the most similar one, so as to define an identification code of the most similar one in the plurality sets of data curves as an identification code of the magnetic unit. Accordingly, effective identification information of respective magnetic units is provided for recognition, which solves the problem of the difficult identification that may occur while simultaneously detecting a plurality of magnet units.

### BRIEF DESCRIPTION OF DRAWINGS

FIG. 1 is a structural schematic diagram of a shielded magnetic unit according to the present invention;

FIG. 2A is a schematic diagram of an identification system for the shielded magnetic unit according to the present invention;

FIG. 2B is a functional illustration of the identification system for the shielded magnetic unit according to the present invention;

FIG. 3 is a scheme view of a plurality of sets of contours and characteristic data curves of a shield according to the present invention;

FIG. 4 is a scheme view of an identification method for a magnetic unit including a plurality of shields according to the present invention;

FIG. 5 is a flow chart of a first embodiment of the identification method for the shielded magnetic unit according to the present invention; and

FIG. 6 is a flow chart of a second embodiment of the identification method for the shielded magnetic unit according to the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification, and can be performed or applied by other different specific embodiments.

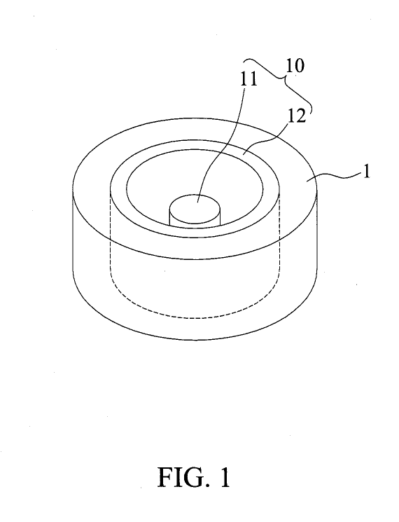

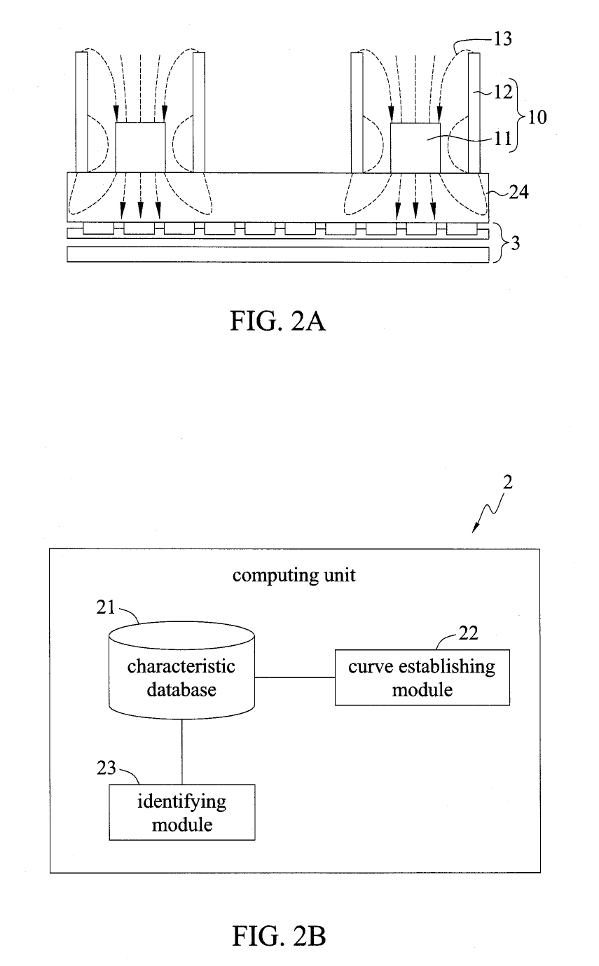

Please referring to FIGS. 1, 2A and 2B, the identification system for a shielded magnetic unit according to the present invention includes at least one magnetic unit 1, a magnetic field sensor 3, and a computing unit 2. The computing unit 2 includes a characteristic database 21, a curve establishing module 22, and an identifying module 23. Please referred to FIG. 1 for the structural features of the magnetic unit 1 of the present invention, where the magnetic unit 1 is an acrylic housing with cylindrical shape and has at least one shield 10 disposed therein. The shield 10 includes at least one magnet 11 and a shielding element 12 disposed at periphery of the magnet 11. In an embodiment, the magnet 11 is a neodymium magnet, and the material of the shielding element 12 is a high permeability material, such as Ni—Fe alloy, μ alloy or galvanized steel, but the present invention is not limited thereto.

In an embodiment, the magnet 11 is fixed the central bottom of the magnetic unit 1 with a laser cutting acrylic. The magnet 11 may also employ other kinds of fixing means, such as adhesion to adhesive material. Also the magnet 11 can be fixed at other positions of the magnetic unit 1, such as the central top and the like. Further, the number of the magnet 11 is at least one or more, but the present invention is not limited thereto. The shielding element 12 surrounds the magnet 11, and the shape of the shielding element may be circular as shown in FIG. 1, and may also be polygonal shape, for example, a square composed of four rectangular galvanized steel sheets, so as to surround the periphery of the magnet 11. It should be appreciated that the present invention does not limit the shape of the shielding element 12 to a surrounding shape. In addition, as shown in FIG. 2A, in order to enable magnetic lines 13 (as illustrated by the dashed lines) of the N pole and S pole of the magnet 11 being directed back to the top or bottom of the magnets 11, the shielding element 12 may only be disposed to surround the periphery of the magnet 11 without being disposed at the top or bottom of the magnet 11. Of course, the shielding element 12 may also be disposed at the top or bottom of the magnet 11 upon the need, and the present invention is not limited thereto.

As shown in FIG. 2B, the computing unit 2 of the present invention may be a computer, tablet or mobile computing device. The magnetic field sensor 3 is constructed by a plurality of magnetic sensing units arranged in array form, the magnetic field sensor 3 senses a magnetic field of the magnet 11 of the shield 10 to generate a magnetic sensing signal, where the magnetic sensing units are Hall effect sensors. In an embodiment, the magnetic field sensor 3 is installed on the back of the screen 24 of the computing unit 2, for example, is directly attached to the back of the touch screen of a cell phone or tablet, but the present invention is not limited thereto. Therefore, the user can place a magnetic unit 1 on a screen 24 of the computing unit 2, the magnetic lines 13 of the magnet 11 inside the shield 10 of the magnetic unit 1 is directed back to the top or bottom of the shield 10 by the shielding element 12, such that the magnetic sensor 3 installed on the back of the screen 24 of the computing unit 2 can detect the magnetic lines 13, so as to generate a magnetic sensing signal. This magnetic sensing signals can be further used for identifying the shield 10. How does the computing unit 2 perform identification of the shield 10 will be further described in the followings.

The characteristic database 21 of the computing unit 2 stores a plurality of sets of characteristic data curves which are established in advance and have different identification codes, respectively. The so-called identification code is used to identify the polarities and intensities of magnets in different shields, for example, the identification code 10 is expressed as S poles with the magnetic field intensity of 10 gauss, and the identification code 20 is expressed as N pole with field intensity of 20 gauss, etc. Therefore, the plurality of sets of characteristic data curves that are stored by the characteristic database 21 are established by shields corresponding to different polarities and intensities in advance, and the plurality of characteristic data curves must be obtained through multiple sampling and the calculation of the mean and standard deviation. The plurality sets of characteristic data curves can serve as a basis of comparison.

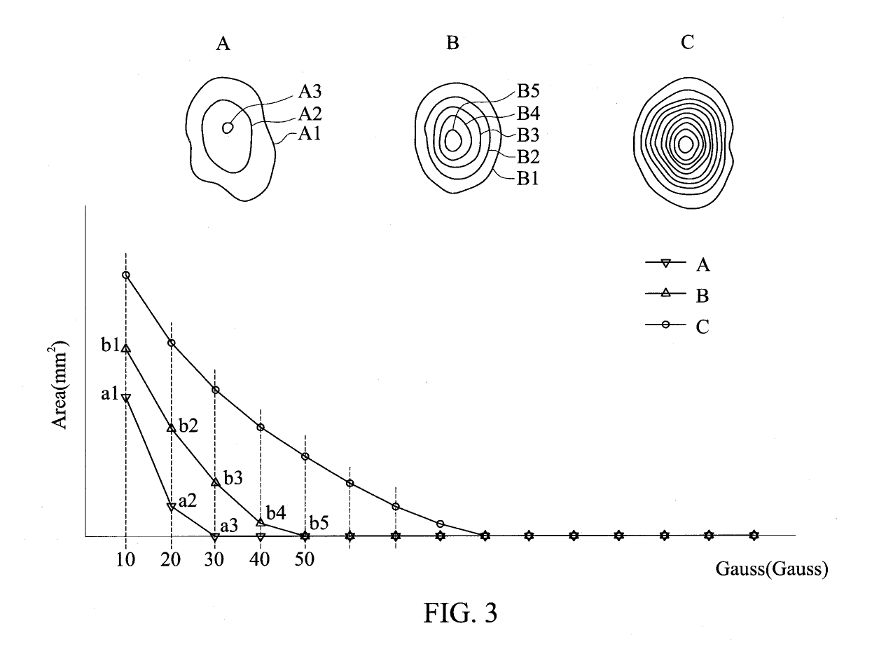

The curve establishing module 22 of the computing unit 2 is utilized to convert the magnetic sensing signals generated by the magnetic sensor 3 to data curves to be identified. Specifically, the magnetic sensing signal is a bitmap image of magnetic field comprising intensity distribution information of magnetic fields of the N pole and S pole. After a plurality of intensity threshold values of magnetic field are applied to the N pole and S pole magnetic fields of the bitmap image of magnetic field, a plurality of contours of different intensities of the magnetic fields of the N pole and S pole are obtained. As shown in FIG. 3, the bitmap image of magnetic field A applies three intensity threshold values of magnetic field, such as 10, 20, and 30 Gauss, and three sets of contours A1, A2, and A3 are obtained; the bitmap image of magnetic field B applies five intensity threshold values of magnetic field, such as 10, 20, 30, 40, and 50 Gauss, and thus five sets of contours B1, B2, B3, B4, and B5 are obtained.

After a plurality of intensity threshold values of magnetic field are applied to the bitmap image of magnetic field to obtain a plurality of contours, the data curves to be identified can be drawn. The method of drawing the data curves to be identified is calculating an area value which represents an area enclosed by the contour, such that the data curves to be identified are drawn by using the area values and corresponding intensity threshold values of magnetic field as two-dimensional coordinates, respectively. For example, data curves to be identified corresponding to the bitmap image of magnetic field A can be presented as connections of area-intensity characteristic points a1, a2, a3 ; and data curves to be identified corresponding to the bitmap image of magnetic field B can be presented as connections of area-intensity characteristic points b1, b2, b3, b4, and b5. In an embodiment, the bitmap image of magnetic field can only apply one magnetic field intensity threshold value to obtain one contour, the present invention is not limited thereto.

Above describes the data curves to be identified, while the characteristic data curves stored in the characteristic database 21 are also drawn by the abovementioned manner, and thus the same description content will not be repeated herein. However, the characteristic data curves can only obtained through several times (e.g., 1000 times) of sampling and the calculation of mean and standard deviation thereof, so the accuracy of the characteristic data curve is higher than the data curve to be identified, and thus the characteristic data curve can serve as the basis of comparison. The characteristic data curve contains information of mean and standard deviation of the curves.

The identifying module 23 of the computing unit 2 is used to identify the data curve to be identified, where the identification method selects one most similar to the data curve to be identified from the plurality sets of characteristic data curves stored in the characteristic database 21. After the one most similar to the characteristic data curve to be identified, the identification code corresponding to the most similar one of the characteristic data curves is defined as an identification code of the magnetic unit 1 corresponding to the data curve to be identified.

In an embodiment, the method of selecting the most similar one performs comparison respectively based on regions of the magnetic field intensity threshold values. Referring again to FIG. 3, for example, the connection of the data curve to be identified at Gaussian region with horizontal coordinates of 10 and 20 can be compared with the connection of area-intensity characteristic points b1 and b2 or with the connection of area-intensity characteristic points a1 and a2. After each region of respective magnetic field threshold values is compared, if the connection of several regions of the data curve to be identified is more similar to the connection of area-intensity characteristic points b1, b2, b3, b4 and b5, then the dimension of the shield 10 of the data curve to be identified can be considered as approximate to the dimension of the shield 10 of the bitmap image of magnetic field B. The method of selecting the most approximate one described in this embodiment is merely one example of the present invention, and thus the present invention is not limited thereto.

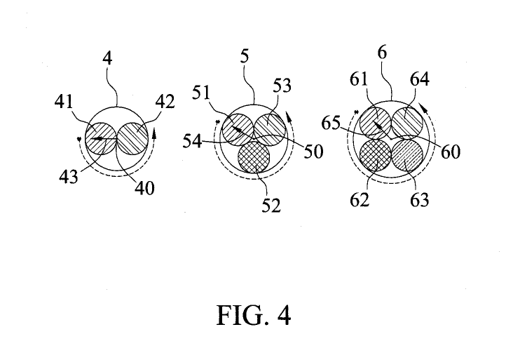

Above-mentioned embodiment is directed to a magnetic unit having only one shield 10 for illustration, while the magnetic unit 1 of the present invention can further have two or more shields disposed therein. Please refer to FIG. 4, for example, two shields 41 and 42 are disposed within a magnetic unit 4 three shields 51, 52 and 53 are disposed within a magnetic unit 5, and four shields 61, 62, 63 and 64 are disposed within a magnetic unit 6.

When the magnetic element 1 only has a single shield 10, the position thereof on the magnetic field sensor 3 is directly based on the shield 10, as shown in FIG. 2A.However, as the magnetic unit 4 has two or more shields 41 and 42 therein, within the magnetic shield member 41, 42, the position thereof on the magnetic field sensor 3 is defined by the position of a center of an inscribed circle 40 of each of the shields 41 and 42, as shown in FIG. 4.

Also, the magnetic unit with two or more shields disposed therein can also provide direction information. The magnetic unit 6 of FIG. 4, for example, has shields 61, 62, 63 and 64 disposed therein, and one of the shields 61, 62, 63 and 64 can be selected as a target shield. For example, if the shield 61 is selected as the target shield, the direction of the magnetic unit 6 on the magnetic field sensor 3 is defined by a directional vector 65 from the center of an inscribed circle 60 to the center of the shield 61 of the magnetic unit 6. In an embodiment, the method of selecting the target shield may be an arbitrary selection, or can be selected by comparing the differences of maximum magnetic field intensities of the N poles and P poles of respective shields and selecting the shield with minimum difference. The invention is not limited thereto. When there are more than two shields disposed in the magnetic unit, an identification code of the magnetic unit can be defined by an equation. For example, in an embodiment, the equation may be:

$$ID = {\sum }_{i = 0}^{k - 1} {B}_{i} \times {N}^{i} ,$$

where ID is the identification code of the magnetic unit, k is a number of all the shields disposed in the magnetic unit, N is a number of IDs that a shield can provide, and B is each of the identification codes corresponding to the shields defined by the identifying module. The magnetic unit 5 of FIG. 4, for example, the identifying module 23 of the computing unit 2 defines identification codes of respective shields 51, 52 and 53. The method of defining the identification code is as previously described, and thus is not repeated herein. Then, one of the shields 51, 52, and 53 is selected as the target shield which serves as a starting point (i.e., i=0 in above equation), and the equation is applied in a counterclockwise or clockwise order. For example, identification codes of the shields 51, 52 and 53 are 3, 2 and 0, respectively. After applying the equation, the calculation of the shield 51 is 3×4⁰ (the calculation of the shield 52 is 2×4¹, and the calculation of the shield 53 is 0×4². Accordingly, the identification code of the magnetic unit 5 is the summation of the three calculations, i.e., 11.

In another embodiment, the equation may be:

$$ID = {\sum }_{i = 0}^{k - 1} {B}_{i} \times {N}^{i} ,$$

where ID is the identification code of the magnetic unit, k is a number of all the shields disposed in the magnetic unit, and B is each of the identification codes corresponding to the shields defined by the identifying module. The magnetic unit 5 of FIG. 4, for example, the identifying module 23 of the computing unit 2 defines identification codes of respective shields 51, 52 and 53. The method of defining the identification code is as previously described, and thus is not repeated herein. Then, one of the shields 51, 52, and 53 is selected as the target shield which serves as a starting point (i.e., i=0 in above equation), and the equation is applied in a counterclockwise or clockwise order. For example, identification codes of the shields 51, 52 and 53 are 3, 2 and 0, respectively. After applying the equation, the calculation of the shield 51 is 3×3⁰, the calculation of the shield 52 is 2×3¹, and the calculation of the shield 53 is 0×3². Accordingly, the identification code of the magnetic unit 5 is the summation of the three calculations, i.e., 9.

With the above-described equations, definition of an identification code of a magnetic unit having two or more shields therein can be efficiently established on the basis of the established plural sets of characteristic data curves of a single shield. However, it should be appreciated that above-described equations are provided for exemplary purpose for different embodiments, and the present invention is not limited thereto.

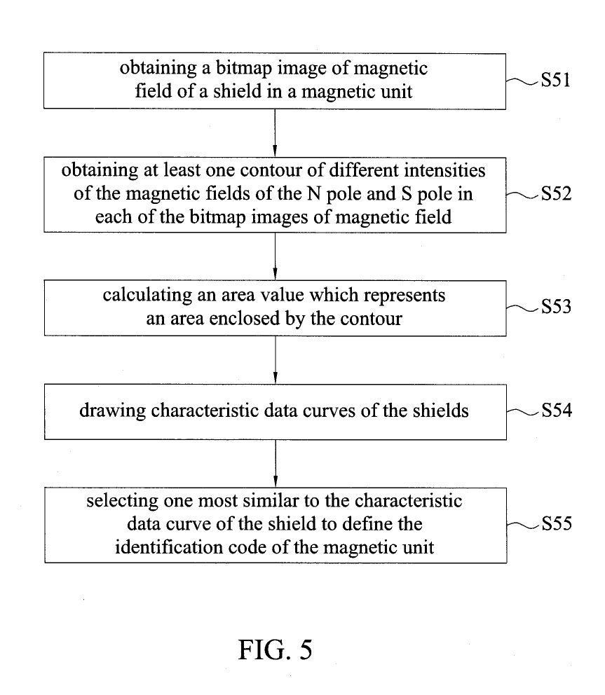

Please refer to FIG. 5, the present invention also provides an identification method for a magnetic unit having only one shield, which comprises the following steps.

In step S 51, a bitmap image of magnetic field of a shield in a magnetic unit is obtained.

In step S 52, at least one magnitude threshold values of magnetic field is applied for magnetic fields of N pole and S pole in each of the bitmap images of magnetic field to obtain at least one contour of different intensities of the magnetic fields of the N pole and S pole in each of the bitmap images of magnetic field. This contour represents that the magnetic field intensity of each point in the contour is identical.

In step S 53, an area value which represents an area enclosed by the contour is calculated, such that the area value and corresponding intensity threshold values of magnetic field can be obtained.

In step S 54, characteristic data curve of the shield is drawn by using the area values and corresponding intensity threshold values of magnetic field as two-dimensional coordinates, respectively. In an embodiment, the intensity threshold value of magnetic field can be plural, such that the obtained contour is also plural and the characteristic data curve is accordingly drawn.

In step S 55, an identification code of the magnetic unit is defined and provided to the system for identification. The method of defying selects one most similar to the characteristic data curve of the shield from at least one set of characteristic data curves with defined identification code, respectively, such that the identification code of the one most similar to the characteristic data curve of the shield is defined as an identification code of the shield. The steps S 51 to S 54 are repeated for a plurality of times to obtain a plurality of characteristic data curves of the shield, so as to calculate a mean and a standard deviation of the characteristic data curves of the shield, such that the at least one set of characteristic data curve with defined identification code including information of the mean and standard deviation of the characteristic data curves is obtained.

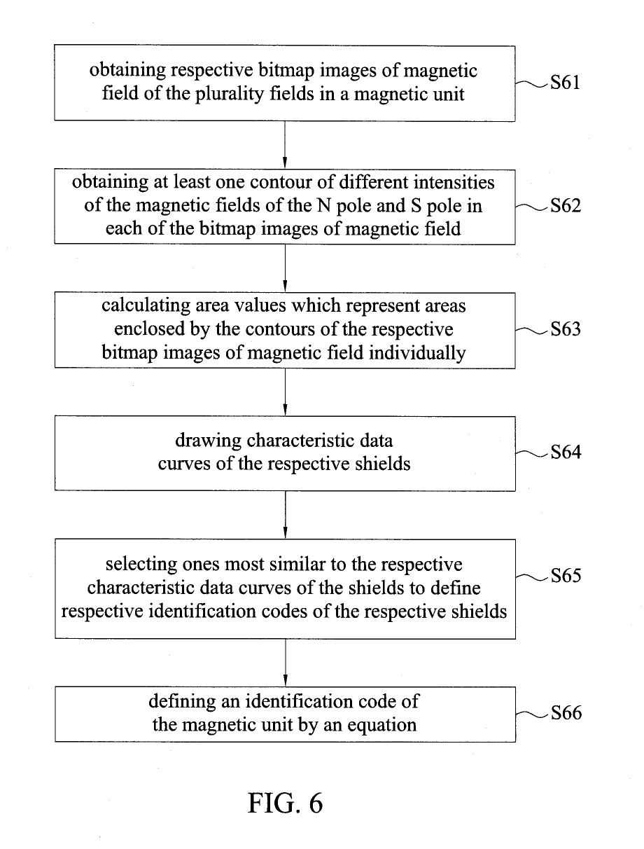

Please refer to FIG. 6, the present invention also provides an identification method for a magnetic unit having a plurality of shields, which comprises the following steps.

In step S 61, respective bitmap images of magnetic field of the plurality fields in a magnetic unit are obtained, where a central position of the magnetic unit is defined by a center of inscribed circles of the shields. In addition, one of the respective shields is selected as a target shield, and the direction information that the magnetic unit can provided is defined by a directional vector from the center of the inscribed circle (i.e., the central position of the magnetic unit) to the center of the target shield.

In step S 62, at least one magnitude threshold value of magnetic field is applied for magnetic fields of N pole and S pole in each of the bitmap images of magnetic field to obtain at least one contour of different intensities of the magnetic fields of the N pole and S pole in each of the bitmap images of magnetic field.

In step S 63, area values which represent areas enclosed by the contours of the respective bitmap images of magnetic field are individually calculated.

In step S 64, characteristic data curves of the respective shields are drawn by using the area values and corresponding intensity threshold values of magnetic field as two-dimensional coordinates, respectively. In an embodiment, the intensity threshold value of magnetic field can be plural, such that the obtained contour is also plural and the characteristic data curve is accordingly drawn.

In step S 65, ones most similar to the respective characteristic data curves of the shields are selected from a plurality of sets of characteristic data curves with defined identification codes, respectively, such that the identification codes of the ones most similar to the characteristic data curves of the shields are defined as identification codes of the shields, respectively.

In step S 66, an identification code of the magnetic unit is defined by an equation. For example, in an embodiment, the equation may be:

$$ID = {\sum }_{i = 0}^{k - 1} {B}_{i} \times {N}^{i} ,$$

where k is a number of all the shields disposed in the magnetic unit, N is a number of IDs that a shield can provide, B is each of the identification codes corresponding to the shields, and ID is the identification code of the magnetic unit. In another embodiment, the equation may be:

$$ID = {\sum }_{i = 0}^{k - 1} {B}_{i} \times {N}^{i} ,$$

k is a number of all the shields disposed in the magnetic unit, and B is each of the identification codes corresponding to the shields defined by the identifying module. It should be appreciated that above-described equations are provided for exemplary purpose for different embodiments, and the present invention is not limited thereto.

Given abovementioned identification system and method for shielded magnetic units according to the present invention, since a shielding element is disposed at periphery of a magnet in a shield of the magnetic unit, the magnetic line of the magnet is directed back inside the shield to reduce the interference occurred while simultaneously detecting a plurality of magnetic units. In addition, a plurality of sets of characteristic data curves are established in advance, such that a data curve to be identified of the shield can be compared with the plurality of sets of data curves to select the most similar one, so as to define an identification code of the most similar one in the plurality sets of data curves as an identification code of the magnetic unit. Accordingly, effective identification information of respective magnetic units is provided for recognition, which solves the problem of the difficult identification that may occur while simultaneously detecting a plurality of magnet units.

In practical application, the present invention can be utilized in the chessboard game. For example, a screen of a tablet can display the chessboard. In use of a plurality of magnetic units and a magnetic field sensor, user is allowed to play a chessboard game on the chessboard of the screen using the magnetic units as tokens. The design of the identification code and position information of the magnetic unit allows the identification system for the magnetic unit to effectively recognize respective magnetic units, such that the respective magnetic units can represent different tokens, and the positions thereof on the chessboard can be further recognized For the magnetic unit having a plurality of shields therein, such magnetic unit can be utilized in a real-time music control system. For example, the magnetic unit serves as a button for adjusting volume of the music by using the direction information provided by the magnetic unit to determine whether the magnetic unit rotates. In addition, the present invention can be further utilized to achieve more interactions, and thus the present invention is not limited to above applications.

The above embodiments only exemplarily specify the concept and effect of the invention, but not intend to limit the invention. Any person skilled in the art can perform modifications and adjustments on the above embodiments without departing the spirit and category of the invention. Accordingly, all modifications and variations completed by those with ordinary skill in the art should fall within the scope of present invention defined by the appended claims. Thus, the present invention should fall within the scope of the appended claims.

What is claimed is:

1. An identification system for a shielded magnetic unit, comprising:
at least one magnetic unit having at least one shield disposed therein, wherein the shield includes at least one magnet and a shielding element disposed at periphery of the magnet;
a magnetic field sensor constructed by a plurality of magnetic sensing units arranged in an array form, wherein the magnetic field sensor senses a magnetic field of the magnet of the shield to generate a magnetic sensing signal; and
a computing unit, comprising:
a characteristic database storing a plurality of sets of characteristic data curves, wherein the plurality of sets of characteristic data curves are established accorindg to shields corresponding to different polarities and intensities, respectively, and each of the plurality of sets of characteristic data curves has an identification code different from one another;
a curve establishing module for converting the magnetic sensing signal into a data curve to be identified; and
an identifying module for selecting one most similar to the data curve to be identified from the plurality of sets of characteristic data curves, such that the identification code of the one most similar to the data curve to be identified is defined as an identification code of the magnetic unit.

2. The identification system of claim 1, wherein the magnetic sensing signal is a bitmap image of the magnetic field comprising intensity distribution information of magnetic fields of an N pole and an S pole.

3. The identification system of claim 2, wherein the data curve to be identified or the plurality of sets of characteristic data curves are obtained by a computation of the bitmap image of the magnetic field, and wherein the computation is performed by following steps:
applying a plurality of intensity threshold values of the magnetic field for the magnetic fields of the N pole and the S pole in the bitmap image of the magnetic field to obtain a plurality of contours of different intensities of the magnetic fields of the N pole and the S pole;
calculating area values each representing an area enclosed by each of the plurality of contours; and
using the area values and corresponding intensity threshold values of the magnetic field as two-dimensional coordinates to draw the data curve to be identified or the plurality of sets of characteristic data curves.

4. The identification system of claim 1, wherein the plurality of magnetic sensing units are Hall sensors, the magnet is a rubidium magnet, and a material of the shielding element is a material with high permeability.

5. The identification system of claim 1, wherein the shielding element surrounds the periphery of the magnet as a circle or a polygon.

6. The identification system of claim 1, wherein the number of the at least one shield is plural, and a central position of the magnetic unit on the magnetic field sensor is defined by a center of an inscribed circle of each of the shields.

7. The identification system of claim 6, wherein one of the plurality of shields is selected as an objective shield, such that a direction vector from the central position of the magnetic unit to the center of the objective shield is defined as a direction of the magnetic unit on the magnetic field sensor.

8. The identification system of claim 7, wherein the identification code of the magnetic unit is defined by an equation.

9. The identification system of claim 1, wherein the computing unit is a computer, a tablet computer or a cell phone, and the magnetic field sensor is disposed on a back of a display of the computing unit.

10. A method of identifying a shielded magnetic unit, comprising steps of:
a) obtaining a bitmap image of a magnetic field of a shield in a magnetic unit;
b) applying a plurality of intensity threshold values of the magnetic field for magnetic fields of an N pole and an S pole in the bitmap image of the magnetic field to obtain at least one contour of different intensities of the magnetic fields of the N pole and S pole;
c) calculating area values each representing an area enclosed by each of the plurality of contours, such that a characteristic data curve of the shield is drawn by using the area values and corresponding intensity threshold values of the magnetic field as two-dimensional coordinates; and
d) selecting one most similar to the characteristic data curve of the shield from at least one set of characteristic data curves with defined identification codes, such that the identification code of the one most similar to the characteristic data curve of the shield is defined as an identification code of the magnetic unit.

11. The method of claim 10, further comprising:
repeating the steps a) to c) for a plurality of times to obtain a plurality of characteristic data curves of the shield; and
calculating a mean and a standard deviation of the characteristic data curves of the shield, such that the characteristic data curve with the defined identification code including information of the mean and standard deviation of the characteristic data curves is obtained.

12. A method of identifying a shielded magnetic unit, comprising steps of:
a) obtaining bitmap images of a magnetic field of each of a plurality of shields in a magnetic unit;
b) applying at least one intensity threshold values of the magnetic field for magnetic fields of an N pole and an S pole in each of the bitmap images of the magnetic field to obtain at least one contour of different intensities of the magnetic fields of the N pole and the S pole in each of the bitmap images of the magnetic field;
c) calculating an area value representing an area enclosed by the contour in each of the bitmap images of the magnetic field, such that characteristic data curves of the shields are drawn by using the area values and corresponding intensity threshold values of the magnetic field as two-dimensional coordinates, respectively;
d) selecting ones most similar to the characteristic data curves of the shields from a plurality of sets of characteristic data curves with defined identification codes, respectively, such that the identification codes of the ones most similar to the characteristic data curves of the shields are defined as identification codes of the shields, respectively; and
e) defining an identification code of the magnetic unit by an equation.

13. The method of claim 12, wherein a central position of the magnetic unit on the magnetic field sensor is defined by a center of inscribed circles of the respective shields.

14. The method of claim 13, wherein one of the plurality of shields is selected as an objective shield, such that a direction vector from the central position of the magnetic unit to the center of the objective shield is defined as direction information provided by the magnetic unit.
